(19) United States
(12) Patent Application Publication
(10) Pub. No.: US 2021/0139314 A1
(43) Pub. Date: May 13, 2021

(54) LINEAR ACTUATOR

(71) Applicant: Innovative Interface Laboratory Corp., Hsinchu City (TW)

(72) Inventor: Yu-Wen Hsu, Taipei City (TW)

(21) Appl. No.: 16/999,334

(22) Filed: Aug. 21, 2020

Related U.S. Application Data
(60) Provisional application No. 62/931,926, filed on Nov. 7, 2019.

(51) Int. Cl. B81B 3/00; H01G 5/16; H02N 1/00

(52) U.S. Cl. CPC B81B 3/0021; H01G 5/16; B81B 2203/051; B81B 2201/033; H02N 1/008

(57) ABSTRACT

The present invention provides a linear actuator. The linear actuator includes: a substrate having a cavity; a first fixed electrode structure fixed on the substrate; an elastic linkage; and a movable electrode structure connected to the substrate through the elastic linkage, wherein: the cavity has a first area; at least one of the first fixed electrode structure and the movable electrode structure has a second projection area on the substrate; and the first area and the second projection area overlap. The linear actuator allows the making of an out-of-plane linear motion motor with a large motion stroke, the robustness of impact, the easy removal of residual process contaminants, an improvement of the efficiency of electrical-to-mechanical energy conversion and the off-axis motion decoupling of movable comb structure.

### CROSS-REFERENCE TO RELATED APPLICATION AND CLAIM OF PRIORITY

This application claims the benefit of U.S. Provisional Application No. 62/931,926, filed on Nov. 7, 2019, in the United States Patent and Trademark Office, the disclosures of which are incorporated herein in their entirety by reference.

### FIELD OF THE INVENTION

The invention relates to a linear actuator, and more particularly to a MEMS linear actuator.

### BACKGROUND OF THE INVENTION

A MEMS actuator has many advantages such as small size, low cost, precise motion control and low power consumption which make it suitable for applications in compact electronic devices or systems. To improve the efficiency of electrical-to-mechanical energy conversion of the MEMS actuator, very narrow structure spacing is usually used. The use of the very narrow structure spacing causes the process residues to be difficultly removed. When the center of gravity of the carried object does not align the center of gravity of the actuator, the carried object would tilt. The tilt of the carried object gives rise to the problem of stress concentration at the contact point between the carried object and the actuator, which in turn would easily cause the carried object to peel from the actuator. As the direction of reaction force from carried object is not well aligned with the pre-determined direction of comb structure, which will cause the comb structure tilt and to having off-axis motion. This off-axis motion can reduce the motion efficiency of comb structure and even causes the moving comb structure stuck with fixed comb structures.

### SUMMARY OF THE INVENTION

The present invention discloses a single-axis linear actuator which serves independently or as a unit of an assembly that overcomes many drawbacks in the prior art.

In accordance with an aspect of the present invention, a linear actuator is provided. The linear actuator includes: a substrate having a cavity; a first fixed electrode structure formed on the substrate; and a movable electrode structure connected to the substrate through an elastic element, wherein the first fixed electrode structure has a first plurality of comb fingers and the movable electrode structure has a second plurality of comb fingers through which the first fixed electrode structure and the movable electrode structure form a capacitor, and the first plurality of comb fingers and the second plurality of comb fingers are disposed above the cavity.

In accordance with a further aspect of the present invention, an actuator is provided. The actuator includes: a substrate having a cavity; a first fixed electrode structure fixed on the substrate; an elastic linkage; and a movable electrode structure connected to the substrate through the elastic linkage, wherein: the cavity has a first area; at least one of the first fixed electrode structure and the movable electrode structure has a second projection area on the substrate; and the first area and the second projection area overlap.

In accordance with another aspect of the present invention, a chip including the actuator is provided.

### BRIEF DESCRIPTION OF THE DRAWINGS

The details and advantages of the present invention will become more readily apparent to those ordinarily skilled in the art after reviewing the following detailed descriptions and accompanying drawings.

FIG. 1 shows the schematic top view of an embodiment of the linear actuator of the present invention.

FIG. 2 is a schematic sectional view of the linear actuator along the section line A-A′ in FIG. 1.

FIG. 3A shows an example of the relationship of the second projection area and the first area.

FIG. 3B shows another example of the relationship of the second projection area and the first area.

FIG. 3C shows an example of the position of the second cavity.

FIG. 4A shows an example in which the center of gravity of the carried object aligns the center of gravity of the linear actuator without the T-bar and the fulcrum hinge.

FIG. 4B shows an example in which the center of gravity of the carried object does not align the center of gravity of the linear actuator without the T-bar and the fulcrum hinge.

FIG. 4C shows an embodiment of the present invention with both the fulcrum hinge and the T-bar.

FIGS. 5A and 5B show the schematic top views of two additional embodiments of the fulcrum hinge.

FIG. 6A shows schematically the chip arrangement on the actuator wafer.

FIG. 6B is a schematic sectional view along the section line B-B′ in FIG. 5A.

FIG. 6C illustrates a protective material coated on the actuator wafer for fixing the movable structures for wafer cutting.

### DETAILED DESCRIPTION OF THE PREFERRED EMBODIMENT

The present invention will now be described more specifically with reference to the following embodiments. It is to be noted that the following descriptions of the preferred embodiments of this invention are presented herein for the purposes of illustration and description only; they are not intended to be exhaustive or to be limited to the precise form disclosed.

Please refer to FIGS. 1-2. FIG. 1 shows the schematic top view of an embodiment of the actuator of the present invention, namely the linear actuator 10000. The linear actuator 10000 is a single-axis linear motion actuator. FIG. 2 is a schematic sectional view of the linear actuator along the section line A-A′ in FIG. 1. The linear actuator 10000 includes a substrate 100, which has a cavity 200 and an electronic element 110. The substrate 100 has a front surface 120 and a rear surface 130, and the cavity 200 extends through the front surface 120 and the rear surface 130 in the z-direction as defined in FIG. 1. The linear actuator 10000 also includes a first fixed electrode structure 300 formed on the substrate 100 so that the first fixed electrode structure 300 is fixed on the substrate 100. The linear actuator 10000 further includes a movable electrode structure 500 connected to the substrate 100 through an elastic element 400, which may be an elastic linkage. The first fixed electrode structure 300 and the movable electrode structure 500 form a capacitor. In the embodiment shown in FIG. 1, both the first fixed electrode structure 300 and the movable electrode structure 500 are comb structures. Therefore, the first fixed electrode structure 300 has a first plurality of comb fingers 320 and the movable electrode structure 500 has a second plurality of comb fingers 520. Each of the first plurality and the second plurality of the comb fingers 320, 520 are parallel to one another. When there is no voltage applied between the first fixed electrode structure 300 and the movable electrode structure 500, the comb fingers 320 of the first fixed electrode structure 300 and the comb fingers 520 of the movable electrode structure 500 do not interdigitate. The capacitor is formed through the first plurality and the second plurality of comb fingers 320, 520. The first plurality and the second plurality of comb fingers 320, 520 are disposed above the cavity 200 to ensure the residual materials from processing can be completely removed through the cavity 200. Therefore, the size of the cavity 200 has to be sufficiently large to completely remove the residual materials; a square with side length slightly more than 10 microns would be sufficiently large. To put it another way, if one looks upward from the cavity 200 on the rear surface 130 and sees any comb finger, then the cavity 200 is sufficiently large. In the present invention, the horizontal projection area of the cavity 200 is defined as a first area 210, and the horizontal projection area of at least one of the first fixed electrode structure 300 and the movable electrode structure 500 is defined as a second projection area 350 on the substrate. FIG. 3A shows an example of the second projection area 350 on the substrate, wherein the second projection area 350 is the projection area of both the first fixed electrode structure 300 and the movable electrode structure 500. The second projection area can be the projection area of only one of the first fixed electrode structure 300 and the movable electrode structure 500. The first area 210 and the second projection area 350 overlap. By “overlap” we mean that the first area 210 and the second projection area 350 overlap a certain percentage, say at least 1% of the second projection area 350, for the size of the cavity 200 to be sufficiently large to completely remove the residual materials, as shown in FIG. 3B, wherein the second projection area 350 is the projection area of the movable electrode structure 500. Without the cavity 200, the comb fingers 320, 520 have to be sparsely arranged to remove the residual materials. But when the comb fingers 320, 520 are sparsely arranged, the efficiency of electrical-to-mechanical energy conversion is low. In other words, the voltage applied between the first fixed electrode structure 300 and the movable electrode structure 500 has to be high. Hence, the cavity 200 allows the removal of residual process contaminants and the improvement of the efficiency of electrical-to-mechanical energy conversion.

The electronic element 110 disposed on the substrate 100 represents the integration of all the motion control electronic components and circuits on the substrate 100. The linear actuator 10000 further includes at least one position sensing capacitor 600 formed by the movable electrode structure 500 and a second fixed electrode structure 610 formed on the substrate 100. The at least one position sensing capacitor 600 is disposed above either the cavity 200 or a second cavity of the substrate 100. If the cavity 200 also allows the removal of residual process contaminants for the at least one position sensing capacitor 600, then there is no need for the second cavity. For example, in the embodiment shown in FIG. 1, the cavity 200 is large enough to remove residual process contaminants for two position sensing capacitors 600, and there is no second cavity. When there is need, a second cavity or cavities can be disposed in the substrate 100 to remove residual process contaminants specifically for the at least one position sensing capacitor 600. For example, in the embodiment shown in FIG. 3C, the second fixed electrode structure 610 of the position sensing capacitor 600 has a horizontal projection area 650, the second cavity has a horizontal projection area 260, and the position sensing capacitor 600 is disposed above the second cavity of the substrate. The at least one position sensing capacitor 600 is used for detecting the displacement of the movable electrode structure 500.

In the embodiment shown in FIG. 1, the elastic element 400, or the elastic linkage, is called a main hinge. The main hinge has a first end, a first center point 450 and a second end, and the first and the second ends are fixed on the substrate 100. Each of the first and the second ends is fixed on the substrate 100 by a first anchor 801. The movable electrode structure 500 has a keel 510 connected with the first center point 450. The linear actuator 10000 further includes a fulcrum hinge 700 connected with the first center point 450 and a T-bar 1100 connected with the fulcrum hinge 700. The T-bar 1100 is adopted for easily holding the carried object attached thereon. In further applications, this single-axis linear motion actuator is designed to be flipped 90 degrees for driving a carried object to move along the out-of-plane direction. The purpose of the fulcrum hinge 700 is to resolve the issue of the carried object peeling from the T-bar 1100 when there is a shear force applied to the connecting point between the fulcrum hinge 700 and the T-bar 1100. Please see FIGS. 4A-4C. FIG. 4A shows an example in which the center of gravity of the carried object 5000 aligns the center of gravity of the linear actuator without the T-bar and the fulcrum hinge. In comparison, FIG. 4B shows an example in which the center of gravity of the carried object 5000 does not align the center of gravity of the linear actuator without the T-bar and the fulcrum hinge. In FIG. 4B, the stress concentrates on the circled area, and thus, a torque is produced. FIG. 4C shows an embodiment of the present invention with both the fulcrum hinge 700 and the T-bar 1100 to avoid the problem arising from FIG. 4B. The fulcrum hinge 700 has low stiffness in the x-direction but high stiffness in the y-direction and z-direction. In other words, the stiffness in the y-direction k_{y} is much greater than the stiffness in the x-direction kₓ, i.e. k_{y}>>kₓ, and the stiffness in the z-direction k_{z} is also much greater than the stiffness in the x-direction kₓ, i.e. k_{z}>>ₓ. High stiffness in the y-direction is necessary to avoid the decrease of displacement in the y-direction. One skilled in the art can design a variety of fulcrum hinges to meet the requirements. FIGS. 5A and 5B show the schematic top view of two embodiments of the fulcrum hinge in addition to the fulcrum hinge 700 shown in FIG. 1 or 4C. For the case without the fulcrum hinge 700, an external x-directional force applied to the carried object may generate a shear force and a moment at the boundary surface between the carried object and the T-bar 1100. The large shear force and/or the moment may cause the carried object to peel from the surface of T-bar 1100. For the case with the fulcrum hinge 700, the external x-directional force applied to the object may lead to a deformation of the fulcrum hinge 700 to reduce the shear force and the moment at the boundary surface between the carried object and the T-bar 1100. In some circumstances, the fulcrum hinge 700 can be omitted if the shear force is negligible.

The linear actuator 10000 further includes at least one pair of constraining hinges 900, wherein each constraining hinge of the at least one pair of constraining hinges 900 has a third end and a fourth end, the third end is connected to either the keel 510 or an outermost comb finger of the second plurality of comb fingers, and the fourth end is fixed on the substrate 100 by a second anchor 802. In the embodiment shown in FIG. 1, there are two pairs of constraining hinges 900. Through a simulation, it is seen that when the y-directional force of 0.05N is applied to the T-bar 1100, the y-directional motion travels up to 500 microns and the deformation of the main hinge still does not reach the fracture strength. In other words, the present invention can be utilized to provide large motion strokes above 500 microns in the out-of-plane direction. When the y-directional and x-directional forces are both 0.05N, the constraining hinges 900 effectively limit the off-axis motion of the movable electrode structure 500. In the Meantime, the fulcrum hinge 700 is also effectively deformed to prevent the carried object from peeling off from the surface of T-bar 1100. The force of 0.05N is equivalent to 1,020 g (g denotes one gravity) when the mass of the carried object is 5 milligrams. Thus, the linear actuator of the present invention can overcome the problem of the robustness of impact.

The linear actuator 10000 further includes a support arm 1200 where the first fixed electrode structure 300 extends therefrom, wherein the support arm 1200 has a fifth end and a sixth end, and each of the fifth and the sixth ends is fixed on the substrate 100 by a third anchor 803.

The actuator wafer at this stage has a lot of chips with the movable structures. How to protect these movable structures in the chips until the actuator wafer being cut to separate the chips is a very important issue. FIGS. 6A-6C illustrate how to protect the movable structures of the linear actuator 10000 for wafer cutting. As shown in FIG. 6A, there is a third cavity 20500 in the substrate at the position of T-bar 1100 before the wafer cutting process. The third cavity 20500 is reserved for the motion strokes of the T-bar 1100. As shown in FIG. 6B, the actuator wafer 20000 is attached to a carrier wafer 30000. As shown in FIG. 6C, a protective material 20100 such as a photoresist or wax is coated on the actuator wafer 20000 for fixing the movable structures for wafer cutting. After the wafer cutting, the carrier wafer 30000 is separated from the actuator wafer 20000, and the protective material 20100 is removed to obtain the chips, each of which includes a linear actuator 10000. Both the separation of wafers and the removal of the protective material 20100 can be easily achieved by applying chemicals.

### EMBODIMENTS

1. A linear actuator, including: a substrate having a cavity; a first fixed electrode structure formed on the substrate; and a movable electrode structure connected to the substrate through an elastic element, wherein the first fixed electrode structure has a first plurality of comb fingers and the movable electrode structure has a second plurality of comb fingers through which the first fixed electrode structure and the movable electrode structure form a capacitor, and the first plurality of comb fingers and the second plurality of comb fingers are disposed above the cavity.

2. The linear actuator according to Embodiment 1, wherein the substrate has an electronic element.

3. The linear actuator according to Embodiment 1 or 2, wherein the substrate has a front surface and a rear surface, and the cavity extends through the front and the rear surfaces.

4. The linear actuator according to any one of Embodiments 1-3, further including a second fixed electrode structure formed on the substrate, wherein at least one position sensing capacitor is formed by the movable electrode structure and the second fixed electrode structure formed on the substrate, and the at least one position sensing capacitor is disposed above one of the cavity and a second cavity of the substrate.

5. The linear actuator according to any one of Embodiments 1-4, wherein the elastic element is a main hinge.

6. The linear actuator according to any one of Embodiments 1-5, wherein the main hinge has a first end, a first center point and a second end, and the first and the second ends are fixed on the substrate.

7. The linear actuator according to any one of Embodiments 1-6, wherein the movable electrode structure has a keel connected with the first center point.

8. The linear actuator according to any one of Embodiments 1-7, further including a fulcrum hinge connected with the first center point.

9. The linear actuator according to any one of Embodiments 1-8, wherein each of the first and the second ends is fixed on the substrate by a first anchor.

10. The linear actuator according to any one of Embodiments 1-9, further including at least one pair of constraining hinges, wherein each constraining hinge of the at least one pair of constraining hinges has a third end and a fourth end, the third end is connected to one of the keel and an outermost comb finger in the second plurality of comb fingers, and the fourth end is fixed on the substrate by a second anchor.

11. The linear actuator according to any one of Embodiments 1-10, further including a T-bar connected with the fulcrum hinge.

12. The linear actuator according to any one of Embodiments 1-11, further including a support arm connected to the first fixed electrode structure, wherein the support arm has a fifth end and a sixth end, and each of the fifth and the sixth ends is fixed on the substrate by a third anchor.

13. An actuator, including: a substrate having a cavity; a first fixed electrode structure fixed on the substrate; an elastic linkage; and a movable electrode structure connected to the substrate through the elastic linkage, wherein: the cavity has a first area; at least one of the first fixed electrode structure and the movable electrode structure has a second projection area on the substrate; and the first area and the second projection area overlap.

14. The actuator according to Embodiment 13, wherein the first fixed electrode structure and the movable electrode structure form a capacitor

15. The actuator according to Embodiment 13 or 14, wherein the substrate has an electronic element.

16. The actuator according to any one of Embodiments 13-15, wherein the substrate has a front surface and a rear surface, and the cavity extends through the front and the rear surfaces.

17. The actuator according to any one of Embodiments 13-16, further including a second fixed electrode structure formed on the substrate, wherein each of the at least one position sensing capacitor is formed by the movable electrode structure and the second fixed electrode structure formed on the substrate, and the at least one position sensing capacitor is disposed above one of the cavity and a second cavity of the substrate.

18. The actuator according to any one of Embodiments 13-17, wherein the elastic element is a main hinge, the main hinge has a first end, a center point and a second end, and the first and the second ends are fixed on the substrate.

19. The actuator according to any one of Embodiments 13-18, further including a support arm connected to the first fixed electrode structure, wherein the support arm has a fifth end and a sixth end, and each of the fifth and the sixth ends is fixed on the substrate by an anchor.

20. A chip including the linear actuator according to any one of Embodiments 1-12.

21. A chip including the actuator according to any one of Embodiments 13-19.

The linear actuator provided by the present invention allows the making of an out-of-plane linear motion motor with a large motion stroke, the robustness of impact, the easy removal of residual process contaminants, an improvement of the efficiency of electrical-to-mechanical energy conversion and the off-axis motion decoupling of movable comb structure.

It is contemplated that modifications and combinations will readily occur to those skilled in the art, and these modifications and combinations are within the scope of this invention.

What is claimed is:

1. A linear actuator, comprising:
a substrate having a cavity;
a first fixed electrode structure formed on the substrate; and
a movable electrode structure connected to the substrate through an elastic element,
wherein the first fixed electrode structure has a first plurality of comb fingers and the movable electrode structure has a second plurality of comb fingers through which the first fixed electrode structure and the movable electrode structure form a capacitor, and the first plurality of comb fingers and the second plurality of comb fingers are disposed above the cavity.

2. The linear actuator as claimed in claim 1, wherein the substrate has an electronic element.

3. The linear actuator as claimed in claim 1, wherein the substrate has a front surface and a rear surface, and the cavity extends through the front and the rear surfaces.

4. The linear actuator as claimed in claim 1, further comprising a second fixed electrode structure formed on the substrate, wherein at least one position sensing capacitor is formed by the movable electrode structure and the second fixed electrode structure, and the at least one position sensing capacitor is disposed above one of the cavity and a second cavity of the substrate.

5. The linear actuator as claimed in claim 1, wherein the elastic element is a main hinge.

6. The linear actuator as claimed in claim 5, wherein the main hinge has a first end, a first center point and a second end, and the first and the second ends are fixed on the substrate.

7. The linear actuator as claimed in claim 6, wherein the movable electrode structure has a keel connected with the first center point.

8. The linear actuator as claimed in claim 6, further comprising a fulcrum hinge connected with the first center point.

9. The linear actuator as claimed in claim 6, wherein each of the first and the second ends is fixed on the substrate by a first anchor.

10. The linear actuator as claimed in claim 9, further comprising at least one pair of constraining hinges, wherein each constraining hinge of the at least one pair of constraining hinges has a third end and a fourth end, the third end is connected to one of the keel and an outermost comb finger in the second plurality of comb fingers, and the fourth end is fixed on the substrate by a second anchor.

11. The linear actuator as claimed in claim 8, further comprising a T-bar connected with the fulcrum hinge.

12. The linear actuator as claimed in claim 10, further comprising a support arm connected to the first fixed electrode structure, wherein the support arm has a fifth end and a sixth end, and each of the fifth and the sixth ends is fixed on the substrate by a third anchor.

13. An actuator, comprising:
a substrate having a cavity;
a first fixed electrode structure fixed on the substrate;
an elastic linkage; and
a movable electrode structure connected to the substrate through the elastic linkage, wherein:
the cavity has a first area;
at least one of the first fixed electrode structure and the movable electrode structure has a second projection area on the substrate; and
the first area and the second projection area overlap.

14. The actuator as claimed in claim 13, wherein the first fixed electrode structure and the movable electrode structure form a capacitor.

15. The actuator as claimed in claim 13, wherein the substrate has an electronic element.

16. The actuator as claimed in claim 13, wherein the substrate has a front surface and a rear surface, and the cavity extends through the front and the rear surfaces.

17. The actuator as claimed in claim 13, further comprising a second fixed electrode structure formed on the substrate, wherein each of the at least one position sensing capacitor is formed by the movable electrode structure and the second fixed electrode structure formed on the substrate, and the at least one position sensing capacitor is disposed above one of the cavity and a second cavity of the substrate.

18. The actuator as claimed in claim 13, wherein the elastic element is a main hinge, the main hinge has a first end, a center point and a second end, and the first and the second ends are fixed on the substrate.

19. The actuator as claimed in claim 13, further comprising a support arm connected to the first fixed electrode structure, wherein the support arm has a fifth end and a sixth end, and each of the fifth and the sixth ends is fixed on the substrate by an anchor.

20. A chip comprising the actuator as claimed in claim 13.
